(19) United States
(12) Patent Application Publication
(10) Pub. No.: US 2013/0328734 A1
(43) Pub. Date: Dec. 12, 2013

(54) ADAPTIVE ANTENNA IMPEDANCE MATCHING

(71) Applicant: Samsung Electronics Co., Ltd., Gyeonggi-do (KR)

(72) Inventor: Surinder THIND, Middlesex (GB)

(21) Appl. No.: 13/911,697

(22) Filed: Jun. 6, 2013

(30) Foreign Application Priority Data
Jun. 6, 2012 (GB) 1209981.8
Jun. 3, 2013 (KR) 10-2013-0063447

(51) Int. Cl. H03H 7/40

(52) U.S. Cl. CPC H03H 7/40
USPC 343/745

(57) ABSTRACT

An apparatus and method of compensating for an antenna impedance mismatch are provided, including obtaining information about a signal-to-noise ratio (SNR) of a signal received by the antenna, determining that an impedance mismatch exists if the obtained information indicates a predetermined condition indicative of an impedance mismatch, and tuning the antenna to compensate for the impedance mismatch.

### PRIORITY

This application claims priority under 35 U.S.C. §119(a) to an application filed in the Great Britain Intellectual Property Office on Jun. 6, 2012 and assigned Serial No. GB 1209981.8, and to a Korean patent application filed in the Korean Intellectual Property Office on Jun. 3, 2013, and assigned Serial No. 10-2013-0063447, the entire disclosures of both of which are incorporated herein by reference.

### BACKGROUND OF THE INVENTION

1. Field of the Invention

The present invention generally relates to adaptive antenna impedance matching, and more particularly, to detecting an indicator of an impedance mismatch, such as a predetermined signal-to-noise ratio condition or a voltage difference across an inductor, and tuning the antenna to compensate for the mismatch.

2. Description of the Related Art

In devices which communicate wirelessly through an antenna, such as mobile telephone handsets, performance can easily be degraded by an antenna impedance mismatch. An antenna impedance mismatch occurs when the antenna impedance is altered by stray capacitance introduced by nearby objects. For example, the antenna impedance can be altered when the handset is placed near a metallic object or when a user holds the handset close to their face or body. An impedance mismatch can cause problems both when the antenna is used as a transmitter and when the antenna is used as a receiver. An impedance mismatch during transmission results in signal loss, which in turn leads to excess battery consumption since the device's power amplifier (PA) output has to be increased to overcome this signal loss. The excess power is dissipated as heat, causing the handset temperature to increase. Similarly, when the device is acting as a receiver, the antenna sensitivity is reduced which results in a reduction in device range and therefore the coverage of service.

Accordingly, there is a need to minimize the antenna impedance mismatch experienced by a device during use. A well matched antenna may only suffer a fraction of a decibel (dB) coupling loss, whereas losses in a badly matched antenna may be as high as a few dB, e.g., 2 to 3 dB or more. One current solution is to directly measure the return loss (RL) in a transmitted signal and then tune the antenna to increase the RL. However, this approach has the drawback that a portion of the transmitted signal has to be coupled off and monitored to detect the transmitted signal power, reducing the transmission signal strength. Also, this method is not suitable for use when the antenna is being used as a receiver, since the received signal strength is too low for the return loss to be detectable and so the RL cannot be directly measured.

Therefore, a need exists for an apparatus and method for compensating for antenna impedance mismatch.

### SUMMARY OF THE INVENTION

According to an embodiment of the present invention, there is provided an apparatus for compensating for an antenna impedance mismatch, the apparatus comprising an antenna mismatch detection module for obtaining information about a signal-to-noise ratio (SNR) of a signal received by an antenna, and determining that an impedance mismatch exists if the obtained information indicates a predetermined condition indicative of an impedance mismatch; and an antenna tuning module for tuning the antenna to compensate for the impedance mismatch.

According to another embodiment of the present invention, there is provided an apparatus for compensating for an antenna impedance mismatch, the apparatus comprising an antenna mismatch detection module comprising a differential amplifier for detecting a first voltage indicating an input voltage of an antenna and a second voltage indicating an output voltage of a power amplifier (PA), and outputting a signal indicating an impedance mismatch if the first and second voltages are different, the output signal being proportional to a voltage difference between the first and second voltages; and an antenna tuning module for tuning the antenna to compensate for the impedance mismatch.

According to yet another embodiment of the present invention, there is provided a method for compensating for an antenna impedance mismatch, the method comprising obtaining information about a signal-to-noise ratio (SNR) of a signal received by the antenna; determining that an impedance mismatch exists if the obtained information indicates a predetermined condition indicative of an impedance mismatch; and tuning the antenna to compensate for the impedance mismatch.

According to a further embodiment of the present invention, there is provided a method for compensating for an antenna impedance mismatch, the method comprising detecting a first voltage indicating an input voltage of an antenna and a second voltage indicating an output voltage of a power amplifier(PA), outputting a signal indicating an impedance mismatch if the first and second voltages are different, and tuning the antenna to compensate for the impedance mismatch based on the output signal, wherein the output signal is proportional to a voltage difference between the first and second voltages.

### BRIEF DESCRIPTION OF THE DRAWINGS

Embodiments of the present invention will now be described, by way of example only, with reference to the accompanying drawings, in which:

FIGS. 1A and 1B illustrate an apparatus for compensating for the impedance mismatch of an antenna, according to an embodiment of the present invention;

FIG. 2 illustrates the apparatus of FIG. 1 in more detail;

FIG. 3 illustrates an apparatus for compensating for the impedance mismatch of an antenna based on the signal-to-noise ratio (SNR) of a received signal, according to an embodiment of the present invention;

FIG. 4 illustrates a method of compensating for the impedance mismatch of an antenna based on the signal-to-noise ratio (SNR) of a received signal, according to an embodiment of the present invention;

FIGS. 5A and 5B illustrate a method of compensating for the impedance mismatch by monitoring the SNR and a received signal strength indicator (RSSI) of a received signal, according to an embodiment of the present invention;

FIG. 6 illustrates an apparatus for compensating for the impedance mismatch of an antenna based on inductor voltage, according to an embodiment of the present invention;

FIG. 7 illustrates an apparatus for compensating for the impedance mismatch of an antenna based on inductor voltage, according to an embodiment of the present invention;

FIG. 8 illustrates a method of compensating for the impedance mismatch of an antenna based on inductor voltage, according to an embodiment of the present invention;

FIG. 9 illustrates an apparatus for compensating for antenna impedance mismatch including a signal conditioning module, according to an embodiment of the present invention;

FIG. 10 illustrates an apparatus for compensating for antenna impedance mismatch including a signal conditioning module, according to an embodiment of the present invention; and

FIGS. 11 to 14 illustrate alternative antenna tuning modules, according to embodiments of the present invention.

### DETAILED DESCRIPTION OF EMBODIMENTS OF THE PRESENT INVENTION

Hereinafter, various embodiments of the present invention will be described with reference to the accompanying drawings. In the following description, the same elements will be designated by the same reference numerals although they are shown in different drawings. Further, various specific definitions found in the following description are provided only to help general understanding of the present invention, and it will be apparent to those skilled in the art that the present invention can be implemented without such definitions. Further, in the following description of the present invention, a detailed description of known functions and configurations incorporated herein will be omitted when it may make the subject matter of the present invention rather unclear.

According to an embodiment of the present invention, an apparatus for compensating for antenna impedance mismatch includes an antenna mismatch detection module configured to obtain information about a signal-to-noise ratio SNR of a signal received by the antenna and to determine that an impedance mismatch exists if the obtained information indicates that a predetermined condition indicative of an impedance mismatch is met, and an antenna tuning module controllable to tune the antenna to compensate for the impedance mismatch.

According to one or more embodiments of the present invention, the antenna mismatch detection module determines that the predetermined condition is met if a rate of change of the SNR of the received signal over time is below a predetermined threshold rate of change, and/or the magnitude of the SNR of the received signal is below a first predetermined threshold SNR, and/or the SNR of the received signal has decreased by at least a predetermined amount over a predetermined time period.

According to an embodiment of the present invention, the antenna mismatch detection module determines that the predetermined condition is met if a received signal strength indicator (RSSI) of the received signal is below a predetermined threshold RSSI. According to a further embodiment of the present invention, if the RSSI of the received signal is above the predetermined threshold RSSI, the antenna mismatch detection module determines that the predetermined condition is still met if the magnitude of the SNR of the received signal is below a second predetermined threshold SNR.

According to an embodiment of the present invention, the antenna tuning module compensates for the impedance mismatch by tuning the antenna by a first predetermined frequency increment.

According to an embodiment of the present invention, after tuning the antenna by the first predetermined frequency increment, the antenna mismatch detection module determines whether the SNR of the received signal has increased, and, if it is determined that the SNR has increased, the antenna mismatch detection module controls the antenna tuning module to repeatedly tune the antenna in the same direction as the first predetermined frequency increment until no further increase in the SNR is obtained, at which time the antenna mismatch detection module controls the antenna tuning module to tune the antenna by a second predetermined frequency increment opposite in sign to the first predetermined frequency increment.

After tuning the antenna by the second predetermined frequency increment, the antenna mismatch detection module determines whether the SNR of the received signal has increased, and, if it is determined that the SNR has increased, the antenna mismatch detection module controls the antenna tuning module to repeatedly tune the antenna in the same direction as the second predetermined frequency increment until no further increase in the SNR is obtained, at which time the antenna mismatch detection module controls the antenna tuning module to apply no further tuning to the antenna, unless a new impedance mismatch is subsequently detected.

According to an embodiment of the present invention, the antenna mismatch detection module periodically checks, when repeatedly tuning the antenna, whether the SNR has decreased to a predetermined acceptable SNR level, and stops tuning the antenna if it is determined that the predetermined acceptable SNR level has been reached.

According to an embodiment of the present invention, the antenna tuning module comprises a tuning circuit connected to an input of the antenna, the tuning circuit including a variable capacitor arranged such that a tuning voltage can be applied to a terminal of the variable capacitor to tune the antenna impedance by controlling the electrical reactance of the tuning circuit. According to a further embodiment of the present invention, the tuning circuit includes a capacitor or an inductor having a first terminal connected to the antenna input and a second terminal connected to the terminal of the variable capacitor that is arranged to receive the tuning voltage.

According to another embodiment of the present invention, an apparatus for compensating for antenna impedance mismatch includes an antenna mismatch detection module, including a differential amplifier configured to detect a first voltage derived from a voltage at an antenna input and a second voltage derived from a voltage at a power amplifier (PA) output, the antenna input and power amplifier output being connected by an inductor, and to output a signal indicating an impedance mismatch if the first and second voltages are different, the output signal being proportional to a voltage difference between the first and second voltages, and an antenna tuning module controllable to tune the antenna to compensate for the impedance mismatch.

According to an embodiment of the present invention, the antenna tuning module comprises a tuning circuit connected to an input of the antenna, the tuning circuit including a variable capacitor arranged such that a tuning voltage can be applied to a terminal of the variable capacitor to tune the antenna impedance by controlling the electrical reactance of the tuning circuit, and a gain of the differential amplifier may be selected so that the output signal can be applied to the terminal of the variable capacitor as the tuning voltage.

According to an embodiment of the present invention, the antenna mismatch detection module further comprises a bridge circuit comprising a first capacitor connected to a node connecting the inductor and the antenna input, a first diode connected between the first capacitor and a node connected to the first input of the differential amplifier, such that a direct current (DC) voltage is applied to the first input, a second capacitor connected between a reference voltage and the node connecting the first diode and the first input, a third capacitor connected to a node connecting the inductor and the PA output, a second diode connected between the third capacitor and a node connected to the second input of the differential amplifier, such that a direct current DC voltage is applied to the second input, and a fourth capacitor connected between the reference voltage and the node connecting the second diode and the second input.

According to an embodiment of the present invention, the first and third capacitors have the same capacitance as each other and the second and fourth capacitors have the same capacitance as each other, such that when the first voltage and the second voltage are the same, the voltage level of the signal output by the differential amplifier is zero.

According to an embodiment of the present invention, the apparatus further comprises a processing module arranged to receive the differential amplifier output signal, to obtain a tuning correction to be applied to the antenna based on the output signal, and to control the antenna tuning module to tune the antenna to apply the tuning correction.

According to an embodiment of the present invention, the processing module obtains the tuning correction by controlling the antenna tuning module to tune the antenna by a first predetermined frequency increment and determines that the impedance mismatch has been reduced after tuning the antenna by the first predetermined frequency increment if the magnitude of the output signal has reduced, wherein if the impedance mismatch has been reduced, the processing module controls the antenna tuning module to repeatedly tune the antenna in the same direction as the first predetermined frequency increment until no further reduction in the impedance mismatch is obtained, and uses the currently tuned value as the tuning correction, and wherein if the impedance mismatch has not been reduced, the processing module controls the antenna tuning module to repeatedly tune the antenna in the opposite direction to the first predetermined frequency increment until no further reduction in the impedance mismatch is obtained, and uses the currently tuned value as the tuning correction.

According to an embodiment of the present invention, the processing module periodically checks, when repeatedly tuning the antenna in the same or opposite direction as the first frequency increment, whether the output signal has decreased to a level indicating an acceptable impedance mismatch, and stops tuning the antenna if it is determined that the acceptable impedance mismatch has been reached and uses the currently tuned value as the tuning correction.

According to an embodiment of the present invention, the apparatus further comprises a signal conditioning module arranged to low-pass filter the differential amplifier output signal to remove high-frequency noise.

According to another embodiment of the present invention, a method of compensating for antenna impedance mismatch includes obtaining information about a signal-to-noise ratio (SNR) of a signal received by the antenna, determining that an impedance mismatch exists if the obtained information indicates that a predetermined condition indicative of an impedance mismatch is met, and tuning the antenna to compensate for the impedance mismatch.

According to one or more embodiments of the present invention, the predetermined condition is met if a rate of change of the SNR of the received signal over time is below a predetermined threshold rate of change, and/or the magnitude of the SNR of the received signal is below a first predetermined threshold SNR, and/or the SNR of the received signal has decreased by at least a predetermined amount over a predetermined time period.

According to an embodiment of the present invention, the predetermined condition is met if a received signal strength indicator RSSI of the received signal is below a predetermined threshold RSSI. According to a further embodiment of the present invention, if the RSSI of the received signal is above the predetermined threshold RSSI, the predetermined condition is still met if a magnitude of the SNR of the received signal is below a second predetermined threshold SNR.

According to an embodiment of the present invention, tuning the antenna to compensate for the impedance mismatch comprises tuning the antenna by a first predetermined frequency increment.

According to further embodiments of the present invention, after tuning the antenna by the first predetermined frequency increment, the method comprises determining whether the SNR of the received signal has increased, and if the SNR has increased, repeatedly tuning the antenna in the same direction as the first predetermined frequency increment until no further increase in the SNR is obtained, or repeatedly tuning the antenna in the same direction as the first predetermined frequency increment until a predetermined acceptable SNR is obtained, or if the SNR has not increased, tuning the antenna by a second predetermined frequency increment opposite in sign to the first predetermined frequency increment.

According to an embodiment of the present invention, after tuning the antenna by the second predetermined frequency increment, the method further comprises determining whether the SNR of the received signal has increased, and if the SNR has increased, repeatedly tuning the antenna in the same direction as the second predetermined frequency increment until no further increase in the SNR is obtained, or repeatedly tuning the antenna in the same direction as the second predetermined frequency increment until a predetermined acceptable SNR is obtained, or if the SNR has not increased, not applying any further tuning to the antenna unless a new impedance mismatch is subsequently detected.

According to an embodiment of the present invention, tuning the antenna may comprise applying a tuning voltage to a terminal of a variable capacitor to tune the antenna impedance by controlling the electrical reactance of a tuning circuit including the variable capacitor.

According to an embodiment of the present invention, the method of compensating for an impedance mismatch of an antenna comprises: receiving an output signal of a differential amplifier arranged to detect a first voltage derived from a voltage at an antenna input and a second voltage derived from a voltage at a power amplifier (PA) output, wherein the antenna input and power amplifier output are connected by an inductor such that the output signal indicates an impedance mismatch if the first and second voltages are different and is proportional to a voltage difference between the first and second voltages, obtaining a tuning correction to be applied to the antenna based on the output signal, and controlling an antenna tuning module to tune the antenna to apply the tuning correction.

According to an embodiment of the present invention, the tuning correction is made by controlling the antenna tuning module to tune the antenna by a first predetermined frequency increment. Whether the impedance mismatch has been reduced after tuning the antenna by the first predetermined frequency increment is determined by whether the magnitude of the differential output signal has been reduced, the method further comprising, if the impedance mismatch has been reduced, controlling the antenna tuning module to repeatedly tune the antenna in the same direction as the first predetermined frequency increment until no further reduction in the impedance mismatch is obtained, and obtaining the currently tuned value as the tuning correction, and, if the impedance mismatch has not been reduced, controlling the antenna tuning module to repeatedly tune the antenna in the opposite direction to the first predetermined frequency increment until no further reduction in the impedance mismatch is obtained, and obtaining the currently tuned value as the tuning correction.

According to further embodiments of the present invention, the method comprises periodically checking, when repeatedly tuning the antenna in the same or opposite direction as the first frequency increment, whether the output signal has decreased to a level indicating an acceptable impedance mismatch, and stopping tuning the antenna if it is determined that the acceptable impedance mismatch has been reached, and obtaining the currently tuned value as the tuning correction.

The method steps as described herein may be performed in hardware, software, or any combination of the two. Thus, embodiments of the present invention include a non-transitory computer-readable storage medium arranged to store a computer program which, when executed by a processor, causes the processor to perform any or all of the method steps as described herein.

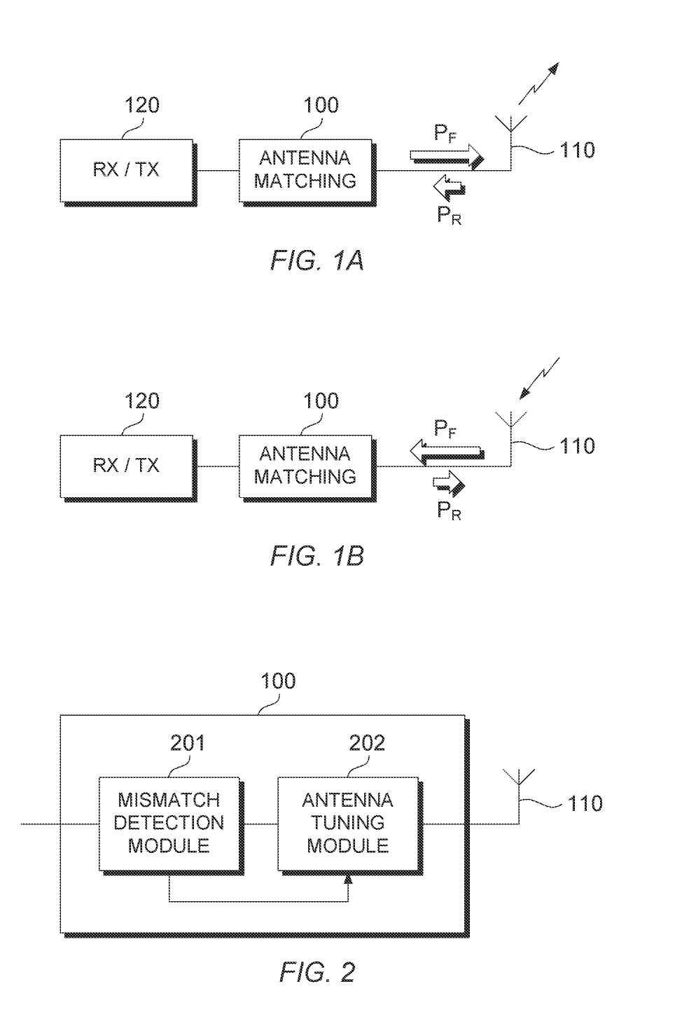

Referring now to FIGS. 1A and 1B, an apparatus for compensating for an impedance mismatch of an antenna is illustrated, according to an embodiment of the present invention. The apparatus can be referred to as an adaptive antenna matching module, since the apparatus applies adaptive impedance matching to the antenna to compensate for a detected impedance mismatch. An impedance mismatch may arise, for example, due to the proximity of a user's body to the antenna while a user is holding the mobile device, or due to proximity of metallic objects.

As shown in FIGS. 1A and 1B, the device includes adaptive antenna matching module 100 connected between antenna 110 and receiver/transmitter (RX/TX) module 120. RX/TX module 120 can include a duplexer to allow simultaneous transmission and reception by antenna 110. Alternatively, RX/TX module 120 can switch between receiving and transmitting modes so that at a given point in time antenna 110 is either receiving or transmitting. Furthermore, in some embodiments of the present invention, adaptive antenna matching module 100 is used in a device which only transmits, or which only receives, i.e., in which a dedicated transmitter or receiver module is provided instead of the dual RX/TX module 120.

The effect of an antenna impedance mismatch is to detune the antenna so that the antenna circuit is resonant at a different frequency than the intended frequency. When the antenna is detuned as a result of an impedance mismatch, the return loss decreases for signals at the desired frequency, i.e., the frequency at which the antenna is supposed to be tuned. The return loss (RL) is defined as the forward signal power (P_{F}) divided by the reflected signal power (P_{R}). The return loss is high when a good impedance match is achieved, as only a small fraction of the forward power will be reflected. When antenna 110 is used to transmit signals, as in FIG. 1A, the forward power is the power sent from RX/TX module 120 to antenna 110. In this case, the reflected power returns to a power amplifier (PA) of the device and is dissipated as heat. On the other hand, when antenna 110 is used to receive signals, as in FIG. 1B, the forward power is the received signal power sent from antenna 110 to RX/TX module 120. In this case, the reflected power does not reach the receiver but is instead dissipated as heat, e.g., in antenna 110 or in intermediate components.

Adaptive antenna matching module 100 is arranged to monitor signals received or transmitted by antenna 110, and to detect a condition indicative of an impedance mismatch of antenna 110. Embodiments of the present invention can detect the impedance mismatch without having to directly measure the forward and reflected signal power. In one embodiment, adaptive antenna matching module 100 monitors the signal-to-noise ratio (SNR) of a received signal and detects when an SNR condition indicative of an antenna mismatch occurs. Examples of SNR conditions that can indicate an impedance mismatch include a large decrease in SNR, or a reduction in SNR without rapid variations that could indicate multipath effects. In another embodiment, adaptive antenna matching module 100 monitors the voltage across an inductor connected between RX/TX module 120 and antenna 110, a voltage difference across the inductor being indicative of an impedance mismatch.

Adaptive antenna matching module 100 is also arranged to respond to the detected impedance mismatch by tuning the antenna to a different frequency. Specifically, adaptive antenna matching module 100 monitors the condition that indicated the impedance mismatch while tuning the antenna to a higher or lower frequency to see if the condition improves. In this way, the antenna can be tuned to compensate for any detuning that has occurred due, for example, to the proximity of an object to the antenna, and the impedance match of the antenna can be improved.

Adaptive antenna matching module 100 is illustrated in more detail in FIG. 2. Specifically, adaptive antenna matching module 100 comprises mismatch detection module 201 and antenna tuning module 202. Mismatch detection module 201 is arranged to monitor the received or transmitted signals to detect a predetermined condition indicative of an impedance mismatch of antenna 110, as described above. If an impedance mismatch occurs, mismatch detection module 201 is arranged to output a signal indicating the impedance mismatch to antenna tuning module 202, which responds to the signal by tuning antenna 110. Various approaches are possible for tuning antenna 110 and will be described later.

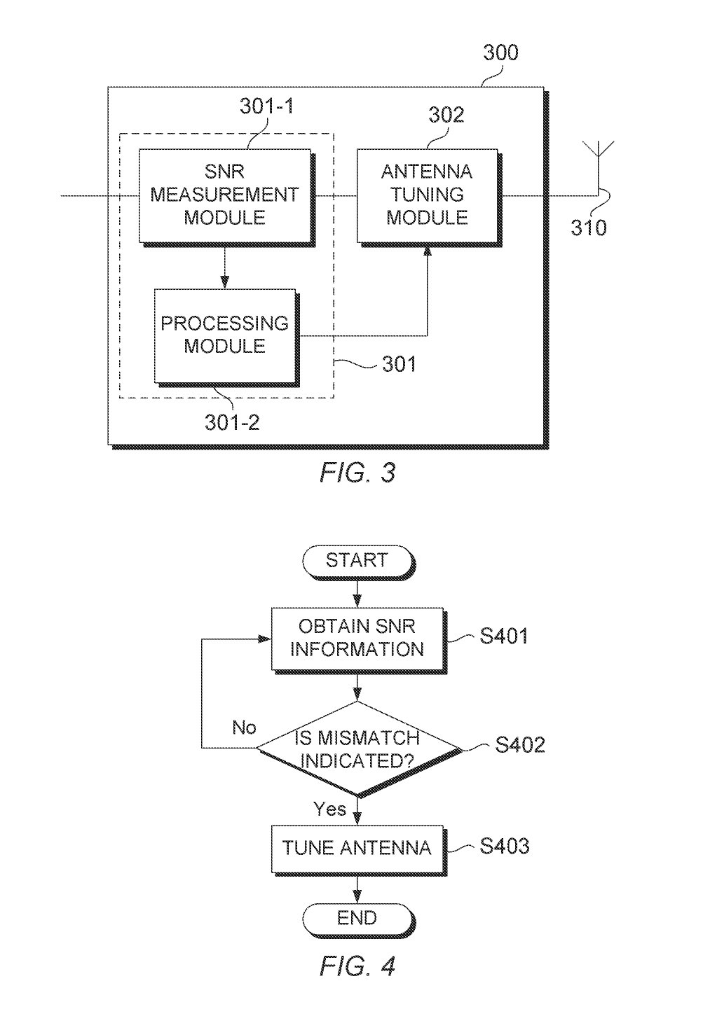

Referring now to FIG. 3, an apparatus for compensating for an impedance mismatch of an antenna based on the signal-to-noise ratio (SNR) of a received signal is illustrated, according to an embodiment of the present invention. Like the adaptive antenna matching module 100 of FIGS. 1A, 1B and 2, apparatus 300 in the present embodiment is connected between antenna 310 and a receiving module. Apparatus 300 includes mismatch detection module 301 comprising SNR measurement module 301-1 arranged to measure an SNR of the signal received by antenna 310, and processing module 301-2 arranged to receive the SNR measurement from SNR measurement module 301-1. However, in another embodiment, SNR measurement module 301-1 may be omitted and processing module 301-2 may obtain information about the SNR from another source. Apparatus 300 further includes antenna tuning module 302 that can be controlled by processing module 301-1 to tune antenna 310 to compensate for the mismatch.

A method by which processing module 301-2 compensates for an impedance mismatch is illustrated in FIG. 4, according to an embodiment of the present invention. In the first step S401, the processing module obtains SNR information. For instance, the processing module can periodically receive an SNR measurement from the SNR measurement module, e.g., it can receive an updated measurement every 1 millisecond (ms). A person of ordinary skill in the art will appreciate that this interval is only an example and other time periods may be chosen instead of 1 ms. In some embodiments, the obtained SNR information enables the processing module to monitor the time-variant behavior of the SNR, such as a rate-of-change of the SNR or a total increase/decrease in SNR over a predetermined time period. To achieve this, the processing module or the SNR measurement module can store information about SNR values of the received signal over a period of time.

Next, in step S402, the processing module checks whether the obtained information indicates that a predetermined SNR condition indicative of an impedance mismatch has been met, i.e., whether an impedance mismatch has occurred. Examples of SNR conditions that can indicate an impedance mismatch will be described later. If the obtained information does not indicate an impedance mismatch, no antenna tuning is required and the process returns to step S401 to continue to monitor the received signal SNR. On the other hand, if the obtained information indicates that an impedance mismatch has occurred, then the processing module proceeds to tune the antenna in step S403. Specifically, the processing module controls the antenna tuning module to tune the antenna to compensate for the impedance mismatch. In some embodiments, the processing module uses a trial-and-error approach to identify the optimum tuning adjustment to be applied to compensate for the mismatch. Specifically, in certain embodiments, the processing module identifies the tuning direction, i.e., positive or negative, that results in an improvement in the condition that indicated the mismatch, and continues to tune the antenna in this direction until no further improvement is observed.

However, other approaches to tuning the antenna are also possible. For example, an impedance mismatch resulting from the handset being held in a particular way may be identified by a characteristic SNR variation, e.g., a characteristic sudden decrease in SNR by a specific amount. In some embodiments, an appropriate tuning adjustment to compensate for this impedance mismatch condition is stored, and, when the characteristic SNR variation is detected, the processing module simply applies this predetermined tuning adjustment without using trial-and-error. In some embodiments, the processing module subsequently checks whether the applied adjustment has worked by checking whether the SNR condition has improved.

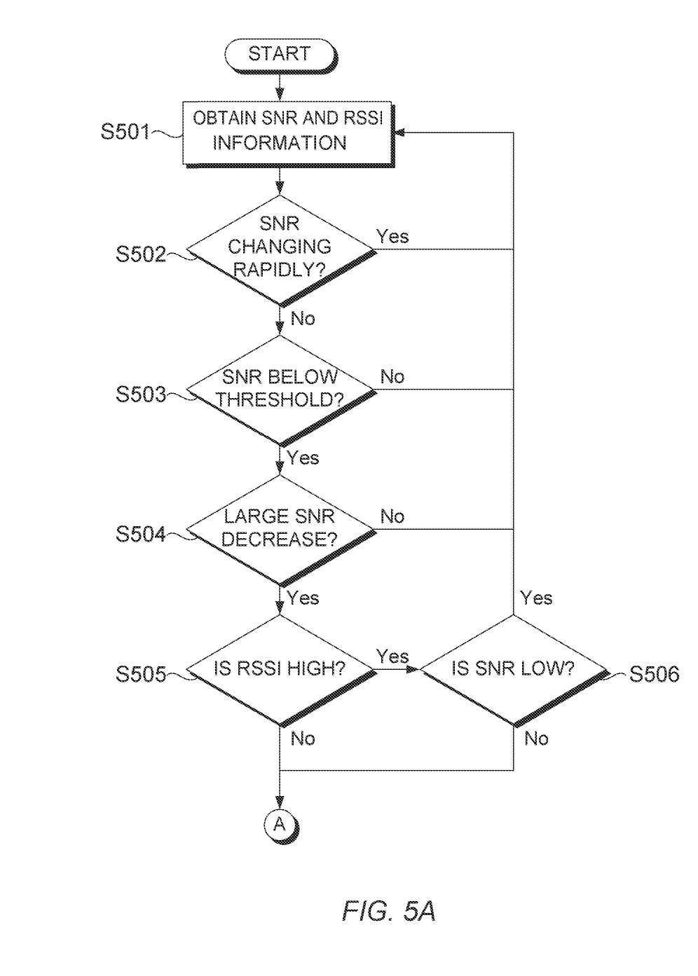

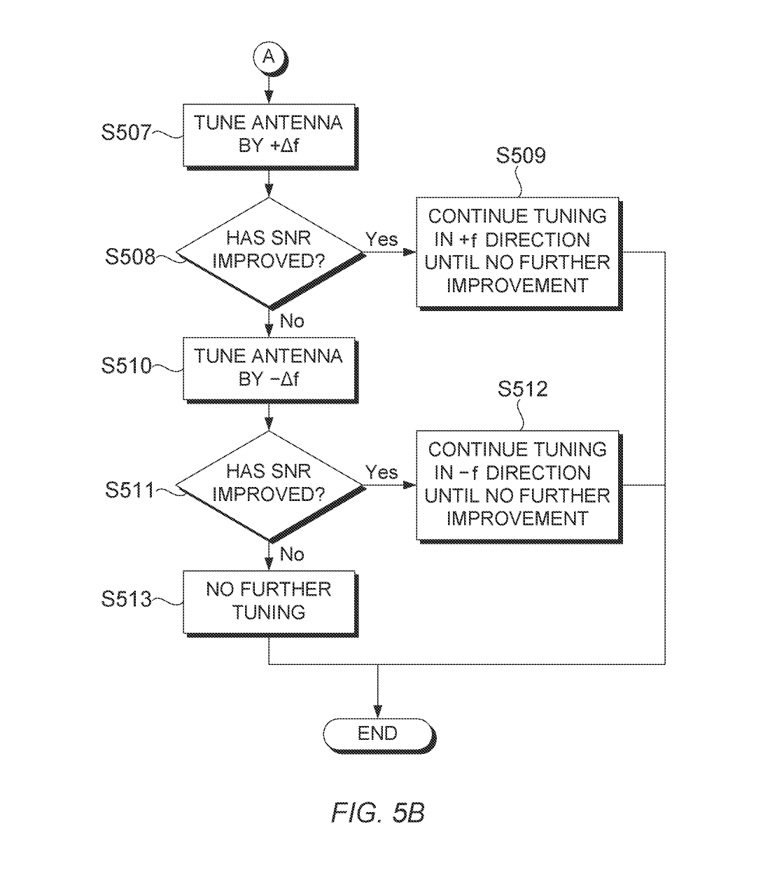

Referring now to FIG. 5, a method of compensating for an impedance mismatch by monitoring the SNR and a received signal strength indicator (RSSI) of a received signal is illustrated, according to an embodiment of the present invention. Like the method of FIG. 4, the method of the present embodiment could be executed by the processing module of FIG. 3. In the first step S501, SNR information about the received signal is obtained. In the present embodiment, this step also includes obtaining information about the RSSI of the received signal. Then, in step S502, it is checked whether the obtained information indicates that the SNR changing rapidly, i.e., whether the rate-of-change is above a predetermined threshold rate-of-change. A high rate of change can indicate multipath effects, which cannot be compensated for by tuning the antenna. Therefore, if the rate of change is above the predetermined threshold, it is assumed that the variation cannot be corrected for and the method returns to step S501 to continue to monitor the SNR and RSSI for a mismatch. This ensures that processing time and power is not wasted unnecessarily by attempting to correct a condition that cannot be corrected at the handset.

On the other hand, if the rate of change of SNR is low enough that it cannot be attributed to multipath effects, i.e., is below the threshold rate-of-change, it is possible to improve the SNR by tuning the antenna, and so the process continues to step S503. In step S503, it is checked whether the magnitude of the SNR is above a predetermined threshold magnitude, for example, 13 dB. If the SNR is above the threshold magnitude, then no correction is required as the SNR is still high enough for the signal to be reliably received, and the process returns to step S501 to monitor the SNR and RSSI. If however the SNR is below the threshold magnitude, then the signal quality is degraded unacceptably and the process continues to step S504. Here, it is checked whether a large SNR decrease has occurred, i.e., whether the SNR magnitude has decreased by a predetermined amount, e.g., 1 dB, in a predetermined time period. If there has not been a large SNR decrease, the process returns to step S501 and continues to monitor the SNR and RSSI. However, if there has been a large decrease then the process proceeds to step S505.

In step S505, it is checked whether the RSSI is high, i.e., above a predetermined threshold RSSI. If the RSSI is high, this may indicate that an impedance mismatch is not responsible for the detected change in SNR, and the process proceeds to step S506 where it is checked whether the SNR is low, i.e., below another predetermined threshold magnitude. Here, the threshold applied at step S506 is lower than the threshold applied at step S503. In some embodiments, step S506 is omitted as the previous check of SNR at step S503 may be sufficient.

If the SNR is low in step S506, then it is assumed that the variation in SNR is due to interference and not an impedance mismatch, so the process returns to step S501 and continues to monitor the SNR and RSSI. On the other hand, if the SNR is relatively high, then it is assumed that the SNR variation is due to an impedance mismatch, so the process continues to step S507 in FIG. 5B and attempts to tune the antenna in order to improve the SNR. Similarly, if the RSSI is determined to be low in step S505, then an impedance mismatch is assumed and the process proceeds directly to step S507 in FIG. 5B to attempt to tune the antenna.

It should be noted that, in other embodiments, one or more of the checks shown in FIG. 5A are omitted. For instance, depending on the handset design, some of the conditions checked in the present embodiment may be a more reliable indicator of antenna mismatch than others, and the method can be adapted accordingly. In some embodiments only one of the checks may be applied, for example, the processing module may only check the rate of change of SNR at step S502, and, if the rate of change is low, it may assume that the change is due to an impedance mismatch and attempt to correct the mismatch by tuning the antenna. Also, in some embodiments, the step of checking the RSSI may be omitted and the processing module may only obtain information about the SNR.

Continuing now with reference to FIG. 5B, in step S507, the processing module controls the antenna tuning module to tune the antenna by a predetermined frequency increment. In the present embodiment, this is a positive frequency increment (+Δf), such that the antenna is tuned to a higher frequency, but in other embodiments a negative frequency increment could be used instead. Then, in step S508 updated SNR information is obtained and it is checked whether the SNR has improved in comparison to the SNR value before the antenna was tuned by the predetermined frequency increment. If the SNR has improved, then in step S509 the processing module continues to tune the antenna in the same frequency direction as the increment applied in step S507, until no further SNR improvement is obtained. In the present embodiment, the antenna is repeatedly tuned by applying the same frequency increment as in step S507, i.e., +Δf, but in other embodiments an increment having the same sign but a different magnitude could be used in step S509.

On the other hand, if in step S508, it is determined that tuning the antenna by the predetermined frequency increment did not improve the SNR, then in step S510 the antenna is tuned in an opposite direction to the increment applied in step S508. In the present embodiment, this is done by tuning by the same magnitude in the opposite direction, i.e., −Δf, but in other embodiments a different step size could be used.

Then, in step S511, updated SNR information is obtained and it is checked whether the SNR has improved after the tuning applied in step S510. If the SNR has improved, then in step S512 the antenna is repeatedly tuned in the same direction as in step S510 until no further improvement is obtained. On the other hand, if no improvement is observed in step S511, then it is determined that the SNR variation is not the result of antenna detuning due to an impedance mismatch, and the method proceeds to step S513 and applies no further tuning. After the process completes in step S509, S512 or S513, the processing module returns to step S501 to continue to monitor the SNR and RSSI for another mismatch.

Methods such as those shown in FIGS. 5A and 5B compensate for an impedance mismatch without having to directly measure the forward and return signal powers. As such, these methods are suitable for use when an antenna is being used to receive signals, in comparison to prior art methods which require the RL to be directly measured and can only be used to correct impedance mismatches in transmission mode.

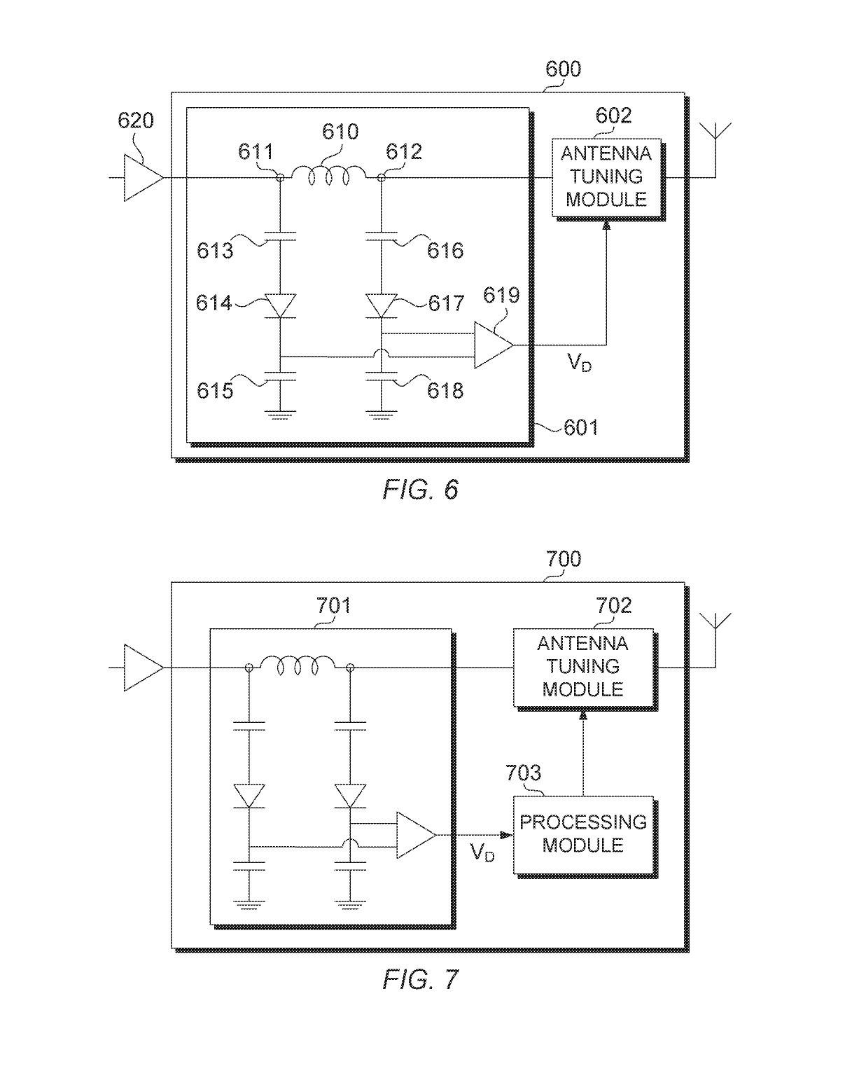

Referring now to FIG. 6, an apparatus for compensating for an impedance mismatch of an antenna based on inductor voltage is illustrated, according to an embodiment of the present invention. Apparatus 600 is connected between the output of power amplifier (PA) 620 and the input of the antenna, and includes antenna mismatch detection module 601 and antenna tuning module 602 similar to the apparatus of FIG. 2. As shown in the embodiment of FIG. 6, antenna mismatch detection module 601 includes a detection circuit arranged to detect when a voltage difference is developed across inductor 610 connected between the PA output and antenna input. Any inductor may be used, i.e., inductor 610 may be one which is already present in the transmission circuit, or may be provided solely for the purpose of detecting an impedance mismatch.

In more detail, antenna mismatch detection circuit 601 includes differential amplifier (diff amp) 619 arranged to detect a first voltage derived from a voltage at first node 611 that connects PA 620 output to inductor 610, and a second voltage derived from a voltage at second node 612 that connects inductor 610 to the antenna. In the present embodiment, the first and second voltages are derived using a bridge circuit. The bridge circuit includes first capacitor 613 connected to first node 611, first diode 614 connected to first capacitor 613, and second capacitor 615 connected between first diode 614 and a reference voltage, in this case ground. The first voltage detected by diff amp 619 is the voltage between first diode 614 and second capacitor 615. The bridge circuit further includes third capacitor 616 connected to second node 612, second diode 617 connected to the third capacitor 616, and fourth capacitor 618 connected between second diode 617 and the reference voltage. The second voltage detected by diff amp 619 is the voltage between second diode 617 and fourth capacitor 618. The first and second diodes 614 and 617 are fast-switching radio frequency (RF) diodes, which convert RF voltages in the transmission signal path to direct current (DC) voltages that can be detected by diff amp 619.

In some embodiments, the capacitors and diode used to derive the first voltage have the same values as those used to derive the second voltage. This ensures that when the voltage across inductor 610 is zero, which will occur when the antenna impedance is perfectly matched, output V_{D} of diff amp 619 will also be zero. If there is an impedance mismatch, a voltage difference will develop across inductor 610, with the result that the first and second voltages become different and diff amp 619 outputs a signal V_{D} proportional to the voltage difference. Diff amp 619 therefore provides output signal V_{D} that indicates an impedance mismatch of the antenna, i.e., if V_{D} has a non-zero value. Also, signal V_{D} is proportional to the voltage across inductor 610, which in turn depends on the extent of impedance mismatch. The value of V_{D} therefore indicates the extent of the impedance mismatch.

As shown in FIG. 6, diff amp 619 output signal V_{D} is input directly to antenna tuning module 602 to tune the antenna. Various tuning circuits are described later, but in the present embodiment diff amp 619 output signal V_{D} is applied directly to change the reactance of the tuning circuit. The gain of diff amp 619 is selected so that, for the particular tuning circuit used, the magnitude of diff amp 619 output signal V_{D} adjusts the tuning circuit reactance by the appropriate amount to compensate for the impedance mismatch.

As described above, the apparatus of FIG. 6 is used when the antenna is being used to transmit a signal, to ensure that the signal power is sufficient to give a measurable voltage difference across the inductor. However, similar embodiments are possible in the receive signal path, for example, if the differential amplifier is sufficiently sensitive or if an additional amplifier is provided to amplify weak RX signals to a power level at which detection is possible.

Referring now to FIG. 7, an apparatus for compensating for an impedance mismatch of an antenna based on inductor voltage is illustrated, according to an embodiment of the present invention. Apparatus 700 is similar in many respects to apparatus 600 of FIG. 6, and in particular includes antenna mismatch detection module 701 similar to 601 of FIG. 6. As such, a detailed explanation will be omitted here, to maintain brevity. However, unlike apparatus 600 of FIG. 6, in the present embodiment, diff amp output signal V_{D} is sent to processing module 703 which controls antenna tuning module 702. In this embodiment, the gain of the diff amp does not have to be selected according to tuning circuit 702, as diff amp output signal V_{D} is not applied directly to tuning circuit 702.

When the output signal V_{D} from antenna mismatch detection module 701 has a non-zero value, i.e., indicates an impedance mismatch, processing module 703 applies a tuning algorithm in order to obtain a tuning correction that can compensate at least partly for the impedance mismatch. Processing module 703 outputs a tuning voltage to tuning circuit 702 to apply the tuning correction. This approach is flexible because the processor can easily alter the tuning voltage to suit particular conditions.

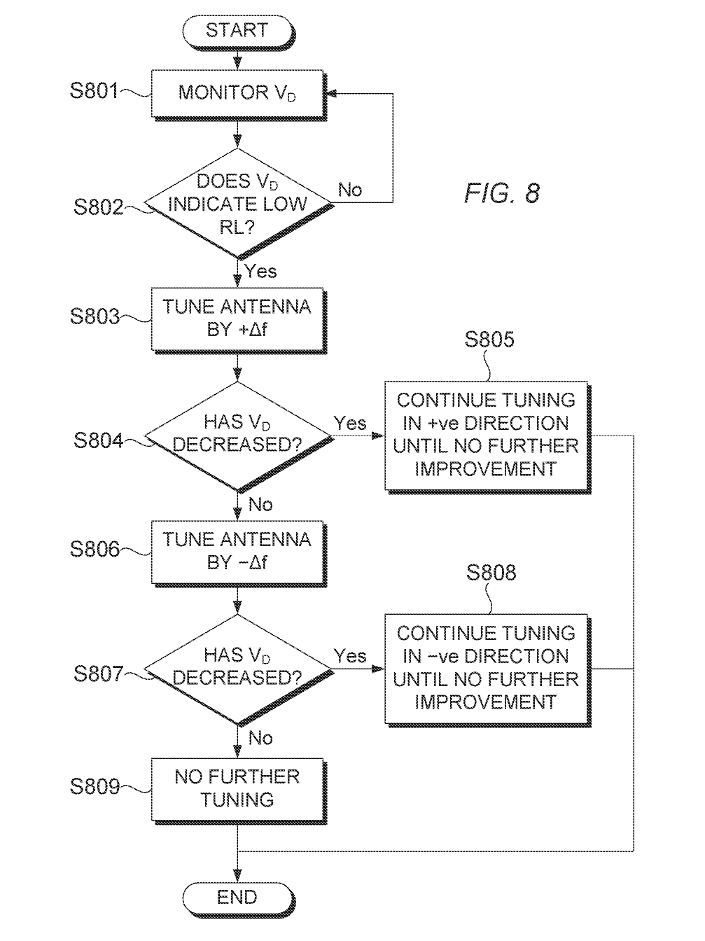

A tuning method suitable for use by processing module 703 of FIG. 7 is illustrated in FIG. 8, according to an embodiment of the present invention. In the first step S801, the processing module monitors diff amp output signal V_{D}. For example, the processing module may check the value of output signal V_{D} every 1 ms, although other time intervals could be used if appropriate. Then, in step S802, the processing module checks whether the current value of output signal V_{D} is indicative of a low RL. Here, various approaches are possible. In one embodiment, any non-zero value of V_{D} could be taken to indicate a low RL which could be the result of an impedance mismatch. However, in the present embodiment, the processing module is arranged to compare the current value of V_{D} against a predetermined threshold value, i.e., a threshold voltage. The threshold voltage can be determined during calibration, as an output voltage of the diff amp that corresponds to an impedance mismatch that is sufficiently high as to require compensation to ensure acceptable performance. If the current value of V_{D} is relatively low, i.e., below the threshold voltage, the process returns to step S801 and continues to monitor output signal V_{D} for an impedance mismatch.

However, if in step S802 it is determined that the output signal V_{D} has a current value above the threshold voltage, then in step S803 the processing module attempts to tune the antenna to correct for the impedance mismatch and obtain an improved, i.e., lower, value of output signal V_{D}. Specifically, in step S803 the processing module controls the antenna tuning module to tune the antenna by a predetermined frequency increment, by setting the tuning voltage provided to the antenna tuning module to a suitable level. In the present embodiment, this is a positive frequency increment, such that the antenna is tuned to a higher frequency, but in other embodiments a negative frequency increment could be used instead. Then, in step S804 an updated value of output signal V_{D} is obtained and it is checked whether the value of V_{D} has decreased in magnitude in comparison to the value before the antenna was tuned by the predetermined frequency increment. A decrease indicates that the voltage across the inductor has dropped, meaning that the antenna mismatch has decreased. If the value of V_{D} has decreased then in step S805 the processing module continues to tune the antenna in the same frequency direction as the increment applied in step S803, until no further improvement in the output signal V_{D}, i.e., no further decrease, is obtained. In the present embodiment, the antenna is repeatedly tuned by applying the same frequency increment as in step S803, i.e., +Δf, but in other embodiments an increment having the same sign but a different magnitude could be used in step S805.

On the other hand, if in step S804 it is determined that tuning the antenna by the predetermined frequency increment did not improve the value of output signal V_{D}, then in step S806 the antenna is tuned in an opposite direction to the increment applied in step S803. In the present embodiment, this is done by tuning by the same magnitude in the opposite direction, i.e., −Δf, but in other embodiments a different step size could be used.

Then, in step S807, an updated value of output signal V_{D} is obtained and it is checked whether the value of V_{D} has decreased in magnitude in comparison to the value before the antenna was tuned in step S806. If the value of V_{D} has decreased, then in step S808 the processing module continues to tune the antenna in the same frequency direction as the increment applied in step S806, until no further improvement in the output signal V_{D}, i.e., no further decrease, is obtained. On the other hand, if no improvement is observed in step S807, then it is determined that the variation in V_{D} is not the result of antenna detuning due to an impedance mismatch, and the method proceeds to step S809 and applies no further tuning. After the process completes in step S805, S808 or S809, the processing module returns to step S801 to continue to monitor output signal level V_{D} for another mismatch.

By following a method such as the one shown in FIG. 8, the processing module can respond to changes in diff amp output signal V_{D} by tuning the antenna to find an optimum tuning correction that compensates for the impedance mismatch. Cases where the change in V_{D} is not the result of an impedance mismatch are also determined and hence unnecessary tuning of the antenna is avoided.

Also, although in steps S805 and S808 of the present embodiment, the antenna is tuned until no further improvement is obtained, in other embodiments the antenna is repeatedly tuned until an acceptably low value of V_{D} is obtained, i.e., a value below a threshold level that indicates an acceptable level of mismatch. This can avoid wasting time and power unnecessarily tuning the antenna when no further improvement is required.

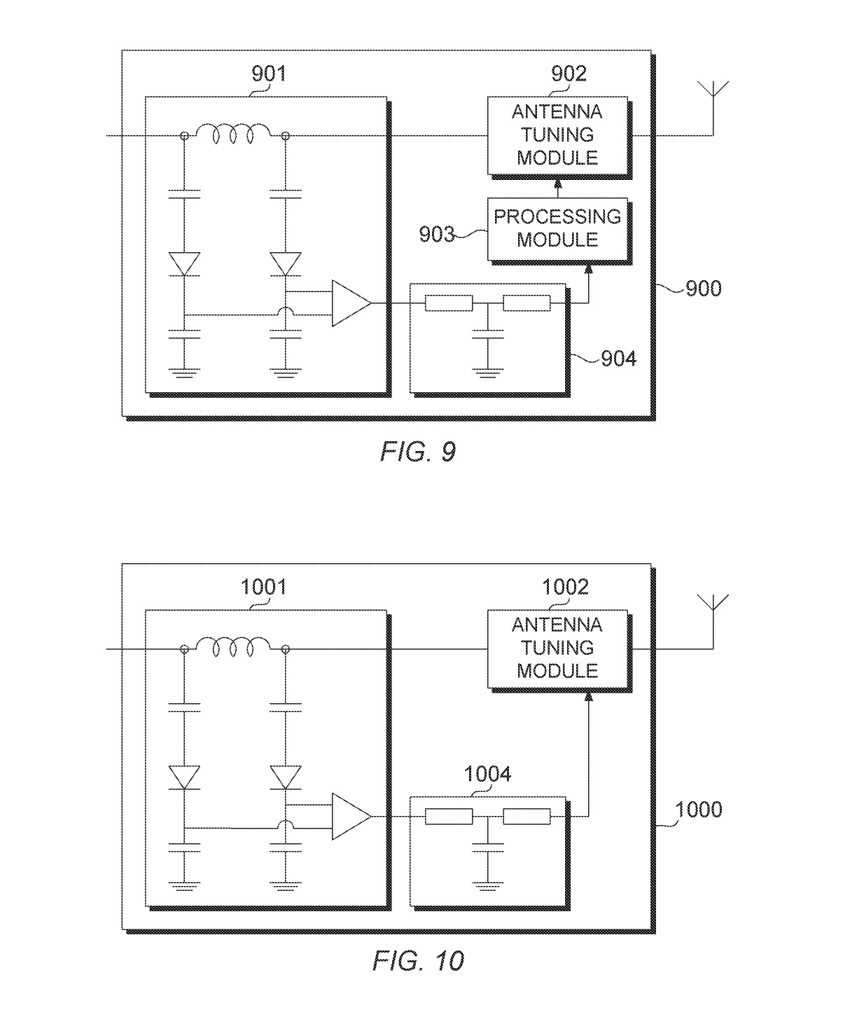

Referring now to FIG. 9, an apparatus for compensating for antenna impedance mismatch including a signal conditioning module is illustrated according to an embodiment of the present invention. Apparatus 900 is similar to 700 shown in FIG. 7, and includes antenna mismatch detection module 901, antenna tuning module 902, and processing module 903. However, apparatus 900 of the present embodiment further includes signal conditioning module 904 connected between the diff amp output of antenna mismatch detection module 901 and the input of processing module 903. The signal conditioning module is arranged as a low-pass filter, to remove any high frequency noise that may be present in diff amp output signal V_{D} and also to increase the attack time to prevent any transient signals from affecting the antenna tuning. Although one particular low-pass filter circuit is illustrated in FIG. 9, a person of ordinary skill in the art will appreciate that other types of low-pass filters could be used and the present invention is not limited to the particular design shown in FIG. 9.

A similar signal conditioning module can also be used in embodiments in which the diff amp output signal is applied directly to the antenna tuning module as a tuning voltage. An example of such an embodiment is shown in FIG. 10, in which apparatus 1000 for compensating for impedance mismatch comprises antenna mismatch detection module 1001, antenna tuning module 1002, and signal conditioning module 1004.

Referring now to FIGS. 11 to 14, various alternative antenna tuning modules are illustrated, according to embodiments of the present invention. In general according to embodiments of the present invention, the antenna tuning module operates by varying the inductance or capacitance of one or more elements in the tuning circuit, to alter the reactance of the circuit and to thereby tune the antenna to be resonant at a different frequency. In the embodiments of FIGS. 11 to 14, a variable capacitor, also referred to as a varactor diode, is used as these are relatively inexpensive and compact. The capacitance of the varactor can be controlled by adjusting the voltage across the varactor. However, in other embodiments, a variable inductor could be used as well as, or instead of, a varactor.

In the embodiment of FIG. 11, antenna tuning module 1102 is connected to the input of antenna 1110 by inductor 1120. Inductor 1120 provides a fixed antenna match. Such inductors are often provided in mobile devices, but are not essential. Therefore inductor 1120 of FIG. 11 is omitted in some embodiments, i.e., where a fixed antenna match is not required.

As shown in FIG. 11, antenna tuning module 1102 includes varactor 1103 connected between the TX/RX signal line (i.e., the line connecting the RX/TX module and the antenna) and ground. Varactor diode 1103 is arranged to be reverse-biased, with the anode connected to ground whilst the cathode is connected to the antenna input. In other embodiments, a reference voltage plane other than ground could be used, and the orientation of the varactor could be reversed if required, i.e., if a high reference voltage is used.

Also, as shown in FIG. 11, tuning voltage V_{T} is applied to the cathode of the varactor, allowing the voltage across the varactor to be controlled in order to tune the varactor capacitance and to thereby tune the antenna to a different frequency. In some embodiments, tuning voltage V_{T} is provided by a processing module such as those shown in FIG. 3, 7 or 9; in other embodiments, it is the diff amp output voltage as shown in FIG. 6 or 10. In some embodiments, tuning voltage V_{T} is subject to signal conditioning before being supplied to antenna tuning module 1100. In the present embodiment, tuning voltage V_{T} is applied to the varactor via resistor 1104 and inductor 1105. Inductor 1105 is used to block RF signals from coupling away from varactor 1103. Capacitor 1106 is also connected between ground and a common node of resistor 1104 and inductor 1105. Capacitor 1106 and resistor 1104 together act as an RC low pass filter to prevent noise in tuning voltage V_{T} from reaching the varactor cathode, and also act as a current limiter.

In the embodiment of FIG. 12, a capacitive tuning circuit is illustrated according to an embodiment of the present invention. This antenna tuning circuit 1202 includes varactor 1203 arranged in a similar manner to 1103 of FIG. 11, except that capacitor 1206 is connected between varactor 1203 and the antenna input. Tuning voltage V_{T} is applied directly to the common node connecting varactor 1203 and capacitor 1206, although in some embodiments additional filtering could be used e.g., a RC filter as shown in FIG. 11. The capacitance C_{C} of capacitor 1206 is arranged to be much larger than varactor 1203 capacitance C_{V}, to reduce the effect of large changes in varactor capacitance C_{V}. This embodiment is useful when sensitive tuning is required.

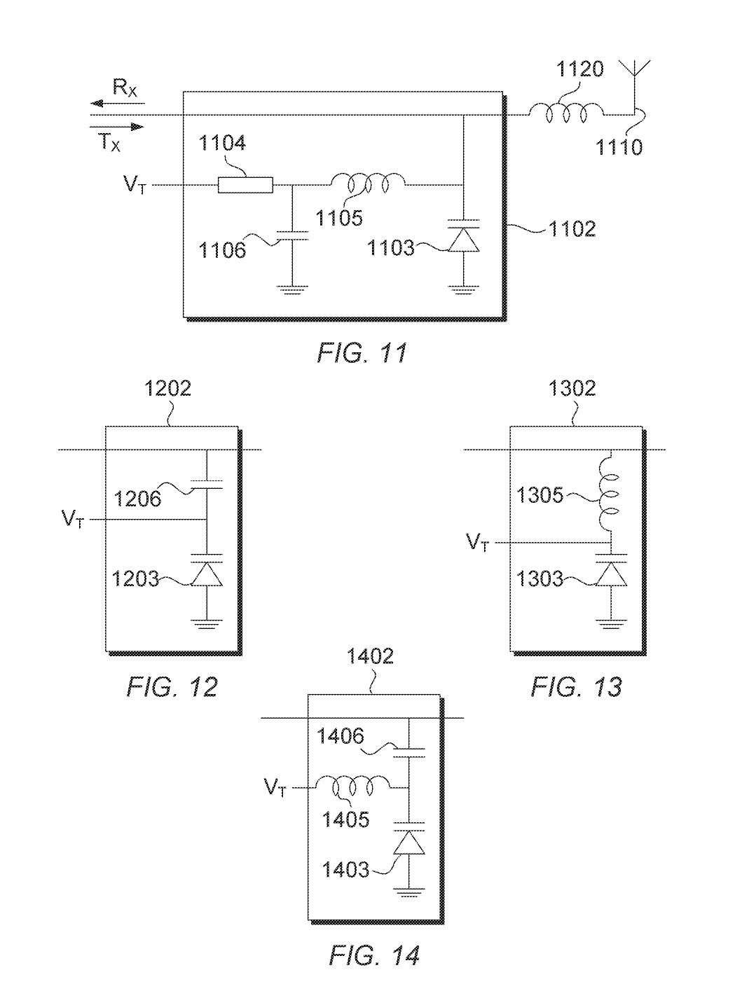

FIG. 13 illustrates a capacitive/inductive tuning circuit 1302 according to an embodiment of the present invention, including varactor 1303 connected between ground and the antenna input, and inductor 1305 connected between varactor 1303 and the antenna input. Tuning voltage V_{T} is applied to a common node connecting varactor 1303 and inductor 1305. The tuning impedance of the circuit in FIG. 13 can be capacitive or inductive depending on the relative inductance/capacitance values of inductor 1305 and varactor 1303.

Finally, a further embodiment of a tuning circuit according to the present invention is illustrated in FIG. 14. This antenna tuning module 1402 includes varactor 1403 and capacitor 1406 connected in series between ground and the antenna input as in FIG. 12, but with the addition of inductor 1405 connected to the common node connecting varactor 1403 and capacitor 1406. Tuning voltage V_{T} is applied via inductor 1405 to block RF signals coupling away from varactor 1403.

Any of the antenna tuning modules illustrated in FIGS. 11 to 14, or any other suitable tuning circuit, may be used in any of the adaptive antenna matching modules described above with reference to FIGS. 1 to 10.

While certain embodiments of the present invention have been shown and described, those of ordinary skill in the art will understand that many variations and modifications of those embodiments are possible without departing from the scope of the invention as defined in the accompanying claims.

What is claimed is:

1. Apparatus for compensating for an antenna impedance mismatch, the apparatus comprising:
an antenna mismatch detection module for obtaining information about a signal-to-noise ratio (SNR) of a signal received by an antenna, and determining that an impedance mismatch exists if the obtained information indicates a predetermined condition indicative of an impedance mismatch; and
an antenna tuning module for tuning the antenna to compensate for the impedance mismatch.

2. The apparatus of claim 1, wherein the antenna mismatch detection module determines that the obtained information indicates the predetermined condition if a rate of change of the SNR of the received signal over time is below a predetermined threshold rate of change, a magnitude of the SNR of the received signal is below a first predetermined threshold SNR, and the SNR of the received signal has decreased by at least a predetermined amount over a predetermined time period.

3. The apparatus of claim 1, wherein the antenna mismatch detection determines that the antenna indicates the predetermined condition if a received signal strength indicator (RSSI) of the received signal is below a predetermined threshold RSSI.

4. The apparatus of claim 3, wherein if the RSSI of the received signal is above the predetermined threshold RSSI, the antenna mismatch detection module determines that the antenna indicates the predetermined condition if a magnitude of the SNR of the received signal is below a second predetermined threshold SNR.

5. The apparatus of claim 1, wherein the antenna tuning module compensates for the impedance mismatch by tuning the antenna by a first predetermined frequency increment.

6. The apparatus of claim 5, wherein after tuning the antenna by the first predetermined frequency increment, the antenna mismatch detection module determines whether the SNR of the received signal is increased, if the SNR is increased, controls the antenna tuning module to repeatedly tune the antenna as the first predetermined frequency increment until no further increase in the SNR is obtained, and if the SNR is not increased, controls the antenna tuning module to tune the antenna by a second predetermined frequency increment opposite in sign to the first predetermined frequency increment.

7. The apparatus of claim 6, wherein after tuning the antenna by the second predetermined frequency increment, the antenna mismatch detection module determines whether the SNR of the received signal is increased, if the SNR is increased, controls the antenna tuning module to repeatedly tune the antenna as the second predetermined frequency increment until no further increase in the SNR is obtained, and if the SNR is not increased, controls the antenna tuning module to stopping tuning of the antenna.

8. The apparatus of claim 1, wherein the antenna tuning module comprises a tuning circuit connected to an input of the antenna, the tuning circuit including a variable capacitor arranged such that a tuning voltage can be applied to a terminal of the variable capacitor to tune the antenna impedance by controlling the electrical reactance of the tuning circuit.

9. An apparatus for compensating for an antenna impedance mismatch, the apparatus comprising:
an antenna mismatch detection module comprising a differential amplifier for detecting a first voltage indicating an input voltage of an antenna and a second voltage indicating an output voltage of a power amplifier (PA), and outputting a signal indicating an impedance mismatch if the first and second voltages are different, the output signal being proportional to a voltage difference between the first and second voltages; and
an antenna tuning module for tuning the antenna to compensate for the impedance mismatch.

10. The apparatus of claim 9, wherein the antenna tuning module comprises a tuning circuit connected to an input of the antenna, the tuning circuit including a variable capacitor arranged such that a tuning voltage can be applied to a terminal of the variable capacitor to tune the antenna impedance by controlling the electrical reactance of the tuning circuit, and
wherein a gain of the differential amplifier is selected so that the output signal can be applied to the terminal of the variable capacitor as the tuning voltage.

11. The apparatus of claim 9, further comprising:
a processing module for receiving output signal of the differential amplifier, obtaining a tuning correction to be applied to the antenna based on the output signal, and controlling the antenna tuning module to tune the antenna to apply the tuning correction.

12. The apparatus of claim 11, wherein the processing module for controlling the antenna tuning module to tune the antenna by a first predetermined frequency increment, determining whether if the magnitude of the output signal is reduced or not after tuning the antenna, if the magnitude of the output signal is reduced, controlling the antenna tuning module to repeatedly tune the antenna as the first predetermined frequency increment until no further reduction in the magnitude of the output signal is obtained, and if the magnitude of the output signal is not reduced, controlling the antenna tuning module to tune the antenna a second predetermined frequency increment opposite direction to the first predetermined frequency increment.

13. The apparatus of claim 12, wherein after tuning the antenna by the second predetermined frequency increment, if the magnitude of the output signal is reduced, the processing module controls the antenna tuning module to repeatedly tune the antenna as the second predetermined frequency increment until no further increase in the SNR is obtained, and if the magnitude of the output signal is not reduced, controls the antenna tuning module to stop tuning of the antenna.

14. The apparatus of claim 11, further comprising:
a signal conditioning module for low-pass filtering the differential amplifier output signal to remove high-frequency noise.

15. A method of compensating for an antenna impedance mismatch, the method comprising:
obtaining information about a signal-to-noise ratio (SNR) of a signal received by the antenna;
determining that an impedance mismatch exists if the obtained information indicates a predetermined condition indicative of an impedance mismatch; and
tuning the antenna to compensate for the impedance mismatch.

16. The method of claim 15, wherein the determining that the obtained information indicates the predetermined condition if a rate of change of the SNR of the received signal over time is below a predetermined threshold rate of change, a magnitude of the SNR of the received signal is below a first predetermined threshold SNR, and the SNR of the received signal has decreased by at least a predetermined amount over a predetermined time period.

17. The method of claim 15, wherein the determining comprises: determining that the antenna indicates the predetermined condition if a received signal strength indicator (RSSI) of the received signal is below a predetermined threshold RSSI.

18. The method of claim 17, wherein the method further comprises: if the RSSI of the received signal is above the predetermined threshold RSSI, determining that the antenna indicates the predetermined condition if a magnitude of the SNR of the received signal is below a second predetermined threshold SNR.

19. The method of claim 15, wherein tuning the antenna comprises tuning the antenna by a first predetermined frequency increment.

20. The method of claim 19, wherein tuning the antenna comprises:
after tuning the antenna by the first predetermined frequency increment, determining whether the SNR of the received signal is increased;
if the SNR is increased, repeatedly tuning the antenna as the first predetermined frequency increment until no further increase in the SNR is obtained; and
if the SNR is not increased, tuning the antenna by a second predetermined frequency increment opposite in sign to the first predetermined frequency increment.

21. The method of claim 20, wherein the method further comprises:
after tuning the antenna by the second predetermined frequency increment, determining whether the SNR of the received signal is increased;
if the SNR is increased, repeatedly tuning the antenna as the second predetermined frequency increment until no further increase in the SNR is obtained; and
if the SNR is not increased, stopping tuning of the antenna.

22. A method of compensating for an impedance mismatch of an antenna, the method comprising:
detecting a first voltage indicating an input voltage of an antenna and a second voltage indicating an output voltage of a power amplifier (PA);
outputting a signal indicating an impedance mismatch if the first and second voltages are different; and
tuning the antenna to compensate for the impedance mismatch based on the output signal;
wherein the output signal is proportional to a voltage difference between the first and second voltages.

23. The method of claim 22, wherein tuning the antenna comprises:
receiving output signal of the differential amplifier;
obtaining a tuning correction to be applied to the antenna based on the output signal; and
tuning the antenna to apply the tuning correction.

24. The method of claim 23, wherein tuning the antenna further comprises:
tuning the antenna by a first predetermined frequency increment;
determining whether the magnitude of the output signal is reduced or not after tuning the antenna;
if the magnitude of the output signal is reduced, repeatedly tuning the antenna as the first predetermined frequency increment until no further reduction in the magnitude of the output signal is obtained; and
if the magnitude of the output signal is not reduced, tuning the antenna a second predetermined frequency increment opposite direction to the first predetermined frequency increment.

25. The method of claim 24, further comprising:
after tuning the antenna by the second predetermined frequency increment, if the magnitude of the output signal is reduced,
repeatedly tuning the antenna as the second predetermined frequency increment until no further increase in the SNR is obtained; and
if the magnitude of the output signal is not reduced, stopping tuning of the antenna.
